(19) United States
(12) Patent Application Publication
(10) Pub. No.: US 2026/0018482 A1
(43) Pub. Date: Jan. 15, 2026

(54) SEMICONDUCTOR PACKAGE INCLUDING A HEAT DISSIPATION METAL MEMBER AND METHOD OF MANUFACTURING THE SAME

(71) Applicant: SAMSUNG ELECTRONICS CO., LTD., SUWON-SI (KR)

(72) Inventor: Youngbae Kim, Suwon-si (KR)

(21) Appl. No.: 19/042,808

(22) Filed: Jan. 31, 2025

(30) Foreign Application Priority Data
Jul. 11, 2024 (KR) 10-2024-0092013

(51) Int. Cl. H01L 23/367; H01L 23/00; H01L 23/31; H01L 23/373; H01L 23/538; H01L 23/552; H01L 25/00; H01L 25/07

(52) U.S. Cl. CPC H01L 23/3675; H01L 23/552; H01L 24/48; H01L 25/074; H01L 23/3107; H01L 23/3736; H01L 23/538; H01L 24/32; H01L 24/73; H01L 25/50; H01L 2224/32145; H01L 2224/32245; H01L 2224/48106; H01L 2224/48227; H01L 2224/73265; H01L 2225/0651; H01L 2225/06562; H01L 2225/06589

(57) ABSTRACT

A semiconductor package includes a redistribution substrate, a chip stack structure disposed on the redistribution substrate and including a plurality of semiconductor chips disposed in a stack, a vertical wiring portion connecting the chip stack structure to the redistribution substrate and including a plurality of vertical wires that extend in a direction perpendicular to an upper surface of the redistribution substrate, a sealing member configured to seal at least a portion the chip stack structure and the vertical wiring portion, and a heat dissipation metal member disposed on side surfaces and an upper surface of the sealing member.

### CROSS-REFERENCE TO RELATED APPLICATION

This application is based on and claims priority under 35 U.S.C. § 119 to Korean Patent Application No. 10-2024-0092013, filed on Jul. 11, 2024, in the Korean Intellectual Property Office, the disclosure of which is incorporated by reference herein in its entirety.

### BACKGROUND

### 1. Technical Field

The inventive concept relates to a semiconductor package, and more particularly, to a semiconductor package including a heat dissipation metal member and a method of manufacturing the same.

### 2. Discussion of Related Art

Electronic apparatuses have become smaller and lighter in response to developments in the electronics industry and the demands of users. Accordingly, semiconductor packages used in these electronic apparatuses have also become smaller and lighter. As the size of the semiconductor packages is reduced, the performance and heat dissipation characteristics of the semiconductor packages become increasingly challenging.

### SUMMARY

The inventive concept includes a semiconductor package in which the entire size of the semiconductor package may be reduced and heat dissipation characteristics of the semiconductor package may be enhanced, and a method of manufacturing the semiconductor package.

Also, aspects of the inventive concept are not limited to the aspects mentioned herein, and other aspects can be clearly understood by one of ordinary skill in the art from the following description.

According to an aspect of the inventive concept, there is provided a semiconductor package including a redistribution substrate, a chip stack structure disposed on the redistribution substrate and comprising a plurality of semiconductor chips disposed in a stack, a vertical wiring portion connecting the chip stack to the redistribution substrate and including a plurality of vertical wires that extend in a direction perpendicular to an upper surface of the redistribution substrate, a sealing member configured to seal at least a portion of the chip stack structure and the vertical wiring portion, and a heat dissipation metal member disposed on side surfaces and an upper surface of the sealing member.

According to another aspect of the inventive concept, there is provided a semiconductor package including a redistribution substrate, a chip stack structure disposed on and spaced apart from the redistribution substrate and including a plurality of semiconductor chips disposed in a stack, a vertical wiring portion connecting the chip stack structure to the redistribution substrate and including a plurality of vertical wires that extend in a direction perpendicular to an upper surface of the redistribution substrate, a sealing member configured to seal at least a portion of the chip stack structure and the vertical wiring portion and to fill a space between the redistribution substrate and the chip stack structure, and a heat dissipation metal member disposed on side surfaces and an upper surface of the sealing member.

According to an aspect of the inventive concept, there is provided a semiconductor package including a redistribution substrate, a chip stack structure disposed on the redistribution substrate and including a plurality of semiconductor chips disposed in a stack, a vertical wiring portion connecting the chip stack structure to the redistribution substrate and including a plurality of vertical wires that extend between an upper surface of the redistribution substrate and a lower surface of each semiconductor chip of the chip stack structure, and a heat dissipation metal member surrounding the chip stack structure and including an upper plate to which an uppermost semiconductor chip of the chip stack structure is adhered by a thermal interface adhesive layer.

### BRIEF DESCRIPTION OF THE DRAWINGS

Embodiments will be more clearly understood from the following detailed description taken in conjunction with the accompanying drawings in which:

FIG. 1A and FIG. 1B are respectively a cross-sectional view and a plan view of a semiconductor package according to an embodiment;

FIG. 2A and FIG. 2B are cross-sectional views of a semiconductor package according to embodiments;

FIG. 3A and FIG. 3B are cross-sectional views of a semiconductor package according to embodiments;

FIGS. 4A through 4L are cross-sectional views showing processes of a method of manufacturing a semiconductor package, according to an embodiment;

FIG. 5 and FIG. 6 are cross-sectional views showing processes of a method of manufacturing a semiconductor package, according to embodiments; and

FIG. 7A and FIG. 7B are cross-sectional views schematically illustrating processes of a method of manufacturing a semiconductor package, according to an embodiment.

### DETAILED DESCRIPTION

Hereinafter, embodiments of the inventive concept will be described in detail with reference to the accompanying drawings. The same reference numerals are used for the same components in the drawings, and redundant descriptions thereof are omitted.

Embodiments described herein are merely exemplary. Embodiments may have various modifications and may take various forms, and some embodiments are illustrated in the drawings and described in detail. However, this is not intended to limit embodiments to a particular modes of practice, and it is to be appreciated that all changes, equivalents, and substitutes that do not depart from the spirit and technical scope of the inventive concept are encompassed in the disclosure.

Any use of examples or exemplary terms is intended merely to elaborate technical ideas and is not intended to limit the scope unless otherwise defined by the claims.

Unless otherwise specified, in this specification, a vertical direction is defined as a z-direction, and a first horizontal direction and a second horizontal direction may each be defined as horizontal directions perpendicular to the Z direction. The first horizontal direction may be referred to as x-direction, and the second horizontal direction may be referred to as y-direction. A vertical level may refer to a height level along the z-direction. The first horizontal direction and a horizontal width may refer to a length in x-direction and/or y-direction, and a vertical length may refer to a length in the z-direction.

Directional phrases and terms may be used for understanding of the disclosure. For example, a top surface may be an upper surface in an illustration. However, this is not intended to limit embodiments. For example, the layer may be turned over, and a top surface thereof may become a bottom surface.

It will be understood that although the terms such as ‘first’ and ‘second’ are used herein to describe various elements, these elements should not be limited by these terms. The terms are only used to distinguish components from each other. For example, a first element referred to as a first element can be referred to as a second element elsewhere without departing from the scope of the appended claims.

In the semiconductor package of an embodiment, heat dissipation characteristics may be improved by including a heat dissipation metal member surrounding sealing member. The heat dissipation metal member may be connected to the ground to perform an electromagnetic interference (EMI) shielding function.

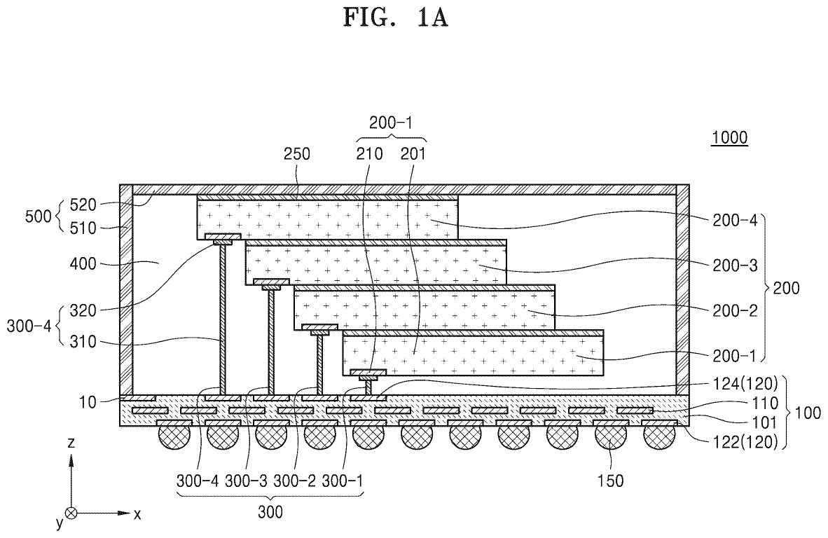

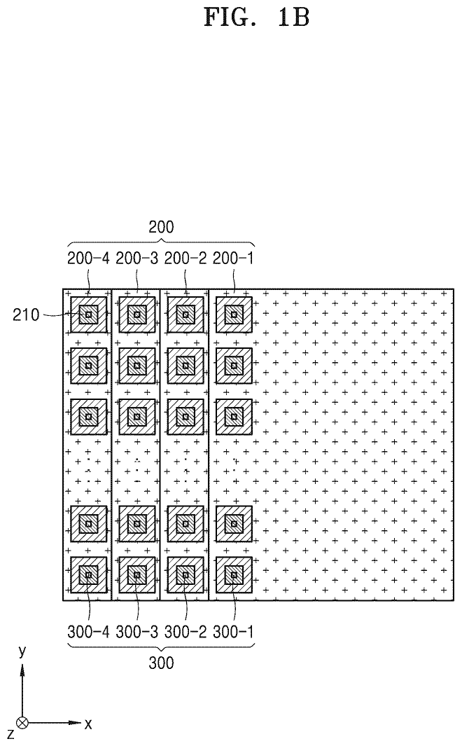

FIG. 1A and FIG. 1B are respectively a cross-sectional view and a plan view of a semiconductor package 1000 according to an embodiment. FIG. 1B is a plan view illustrating at least a portion of a chip stack structure 200, viewed from the bottom to the top.

Referring to FIG. 1A and FIG. 1B, the semiconductor package 1000 according to an embodiment may include a redistribution substrate 100, the chip stack structure 200, a vertical wiring portion 300, a sealing member 400, and a heat dissipation metal member 500.

The redistribution substrate 100 may be disposed below the chip stack structure 200, the vertical wiring portion 300, and the sealing member 400. The redistribution substrate 100 may re-distribute a signal of a chip pad 210 of semiconductor chips of the chip stack structure 200 into an external region of the semiconductor package 1000. The redistribution substrate 100 may include a body insulating layer 101, a redistribution line 110, and a substrate pad 120. The redistribution substrate 100 may include a ground connection 10.

The body insulating layer 101 may be formed of an insulating material. For example, the body insulating layer 101 may be formed of a photo imageable dielectric (PID) or photo imageable polyimide (PIP) resin, and may further include an inorganic filler. However, the material of the body insulating layer 101 is not limited to the above-described materials. For example, the body insulating layer 101 may include polyimide isoindro quindzoline (PIQ), polyimide (PI), or poly-phenylene benzobisoxazole (PBO).

The body insulating layer 101 may have a single layer structure or a multi-layered structure, which may be disposed according to a multi-layered structure of the redistribution line 110. In FIG. 1A, for convenience, the body insulating layer 101 is shown in a single layer structure. When the body insulating layer 101 has a multi-layered structure, all layers of the body insulating layer 101 may include the same material, or at least one of the layers of the body insulating layer 101 may include a different material.

The redistribution line 110 may be disposed in multiple layers within the body insulating layer 101. The layers of the redistribution lines 110 may be connected to each other by a vertical via. The redistribution lines 110 and the vertical via may include copper (Cu), for example. However, the materials of the redistribution line 110 and the vertical via are not limited to Cu. In at least one example, the redistribution lines 110 and the vertical via may include different materials.

The substrate pad 120 may include a lower substrate pad 122 disposed on or in a lower surface of the body insulating layer 101 and an upper substrate pad 124 disposed on or in an upper surface of the body insulating layer 101. The substrate pad 120 may be electrically connected to the redistribution line 110 through the vertical via. In some embodiments, the substrate pad 120 may be directly connected to the redistribution line 110, or a part of the redistribution line 110 may be the substrate pad 120. In some embodiments, the substrate pad 120 may be a part of the redistribution line 110.

A protection layer may be disposed on a lower surface and an upper surface of the redistribution substrate 100, and the substrate pad 120 may be exposed by the protection layer. An external connection terminal 150 may be disposed on the lower substrate pad 122. The external connection terminal 150 may be configured to connect the semiconductor package 1000 to an external device. For example, the external connection terminal 150 may be configured to connect the semiconductor package 1000 to a package substrate of an external system or a main board of an electronic apparatus such as a mobile phone. The external connection terminal 150 may include a conductive material, for example, at least one of solder, tin (Sn), silver (Ag), Cu, or aluminum (Al). Vertical wires of the vertical wiring portion 300 may be connected to the upper substrate pad 124.

The chip stack structure 200 may be disposed above the redistribution substrate 100. The chip stack structure 200 may include a plurality of semiconductor chips. For example, in the semiconductor package 1000 according to an embodiment, the chip stack structure 200 may include four semiconductor chips, including a first semiconductor chip 200-1, a second semiconductor chip 200-2, a third semiconductor chip 200-3, and a fourth semiconductor chip 200-4. However, the number of semiconductor chips of the chip stack structure 200 is not limited to four. For example, the chip stack structure 200 may include two, three, five or more semiconductor chips.

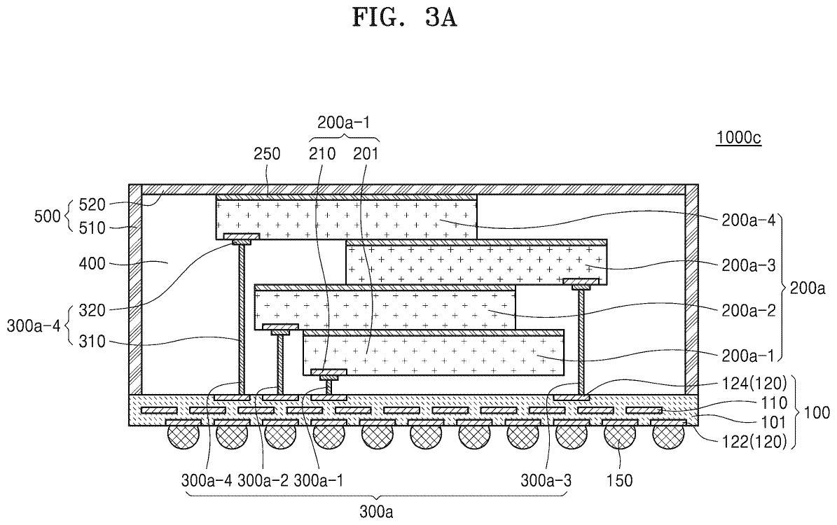

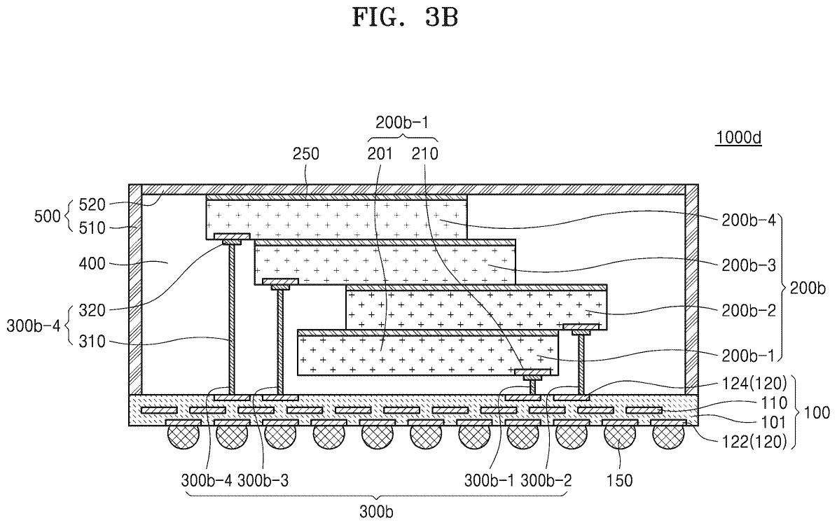

In the chip stack structure 200, the first semiconductor chip 200-1, the second semiconductor chip 200-2, the third semiconductor chip 200-3, and the fourth semiconductor chip 200-4 may be sequentially stacked above the redistribution substrate 100 in a step structure. However, the stack structure of the semiconductor chips of the chip stack structure 200 is not necessarily limited to the step structure. Other stack structures of semiconductor chips of the chip stack structure 200 will be described in more detail with reference to FIG. 3A and FIG. 3B.

Each of the semiconductor chips of the chip stack structure 200 may be substantially the same in terms of structure. Thus, hereinafter, the first semiconductor chip 200-1 will be described as an example. It should be understood that there may be differences between the semiconductor chips that are not related to aspects of the present disclosure. For example, different ones of the semiconductor chips may perform different functions.

The first semiconductor chip 200-1 may include a chip body layer 201 and a chip pad 210. The chip body layer 201 may include a semiconductor substrate, an integrated device layer or a multi-layered distribution layer. The semiconductor substrate may be based on a semiconductor material such as a silicon wafer. The integrated device layer may be formed on the semiconductor substrate and may include a variety of types of devices. For example, the integrated device layer may include various semiconductor devices such as a field effect transistor (FET) such as a planar FET or FinFET, a flash memory, a memory device such as a dynamic random access memory (DRAM), a static random access memory (SRAM), an electrically erasable programmable read-only memory (EEPROM), a phase-change random access memory (PRAM), a magnetoresistive random access memory (MRAM), ferroelectric random access memory (FeRAM), resistive random access memory (RRAM), a logic device such as AND, OR, or NOT, system large scale integration (LSI), a complementary metal oxide semiconductor (CMOS) imaging sensor (CIS), or a micro-electro-mechanical system (MEMS). For example, in the semiconductor package 1000 according to an embodiment, the first semiconductor chip 200-1 may be a DRAM chip in which DRAM devices may be included in the integrated device layer. However, in the semiconductor package 1000 according to an embodiment, the type of the first semiconductor chip 200-1 is not limited to the DRAM chip.

The chip pads 210 may be disposed on a lower surface of the first semiconductor chip 200-1. Thus, the lower surface of the first semiconductor chip 200-1 may be an active surface, and an upper surface of the first semiconductor chip 200-1 may be a non-active surface. The chip pads 210 may be disposed to be biased to any one portion in the x-direction. For example, the chip pads 210 may be disposed on a left portion in the x-direction along the y-direction. In this way, the chip pads 210 may be disposed to be biased in the x-direction in the corresponding semiconductor chip, and the semiconductor chips may be stacked in a step structure in the x-direction in the chip stack structure 200. In other words, a lower surface of each of the semiconductor chips may be exposed to a portion of the left lower surface in the x-direction, based on the step structure, and the chip pads 210 may be disposed on a portion of the exposed lower surface. A lower surface of the first semiconductor chip 200-1, including the chip pad 210, may be entirely covered, with no semiconductor chip disposed below. Although not shown, a chip protection layer may be disposed on the lower surface of the chip body layer 201, and the chip pads 210 may be exposed from the chip protection layer.

The chip pads 210 of each of the first through fourth semiconductor chips 200-1 through 200-4 may be electrically connected to vertical wires of the vertical wiring portion 300. The vertical wires of the vertical wiring portion 300 may include to first vertical wires 300-1, second vertical wires 300-2, third vertical wires 300-3, and fourth vertical wires 300-4. For example, the chip pads 210 of the first semiconductor chip 200-1 may be connected to the first vertical wires 300-1 of the vertical wiring portion 300, the chip pads 210 of the second semiconductor chip 200-2 may be connected to the second vertical wires 300-2 of the vertical wiring portion 300, the chip pads 210 of the third semiconductor chip 200-3 may be connected to the third vertical wires 300-3 of the vertical wiring portion 300, and the chip pads 210 of the fourth semiconductor chip 200-4 may be connected to the fourth vertical wires 300-4 of the vertical wiring portion 300. Each of the first through fourth semiconductor chips 200-1 through 200-4 may be electrically connected to the substrate 100 via the chip pads 210, the vertical wires, and the upper substrate pads 124.

As shown in FIG. 1A, in the chip stack structure 200, the first semiconductor chip 200-1 may be attached to the second semiconductor chip 200-2 via an adhesive layer 250 on the upper surface of the first semiconductor chip 200-1. Also, the second semiconductor chip 200-2 may be attached to the third semiconductor chip 200-3 via the adhesive layer 250, and the third semiconductor chip 200-3 may be attached to the fourth semiconductor chip 200-4 via the adhesive layer 250. The fourth semiconductor chip 200-4 may be attached to an upper plate 520 of a heat dissipation metal member 500 via the adhesive layer 250 on an upper surface of the fourth semiconductor chip 200-4. The adhesive layer 250 may be, for example, a die attach film (DAF). However, the adhesive layer 250 is not limited to a DAF. For example, the adhesive layer 250 may include a material having high thermal conductivity. For example, the thermal conductivity k of the adhesive layer 250 may be between about 5 watt per meter-kelvin (W/(m·K)) and about 14 W/(m·K), and more particularly about 10 W/(m·K). The adhesive layer 250 having high thermal conductivity will be described in more detail in the description of the heat dissipation metal member 500.

The vertical wiring portion 300 may include a plurality of vertical wires. For example, the vertical wiring portion 300 may include first through fourth vertical wires 300-1 through 300-4. As may be seen from FIG. 1B, the first through fourth vertical wires 300-1 through 300-4 of the vertical wiring portion 300 may be connected to the corresponding first through fourth semiconductor chips 200-1 through 200-4. Thus, in proportion to a separation distance of the first through fourth semiconductor chips 200-1 through 200-4 from the redistribution substrate 100, the length in the vertical direction (i.e., the z-direction) may increase in the order of the first vertical wire 300-1, the second vertical wire 300-2, the third vertical wire 300-3, and the fourth vertical wire 300-4.

The first to fourth vertical wires 300-1 through 300-4 may have substantially the same structure and material as each other, except that the lengths thereof may be different in the z-direction. Thus, when one of the fourth vertical wires 300-4 is described, the fourth vertical wire 300-4 may be formed of, for example, gold (Au), Cu, silver (Ag), Al, or the like. In the semiconductor package 1000 according to an embodiment, the fourth vertical wire 300-4 may be formed of Au, for example.

The fourth vertical wire 300-4 may include an extension portion 310 and a contact portion 320. The extension portion 310 may extend from the contact portion 320 downward in the z-direction. The contact portion 320 may be disposed at an upper end portion of the extension portion 310 and coupled to a corresponding semiconductor chip, for example, the chip pad 210 of the fourth semiconductor chip 200-4. As may be seen from FIG. 1B, the contact portion 320 may have a larger area than the extension portion 310 on an xy plane.

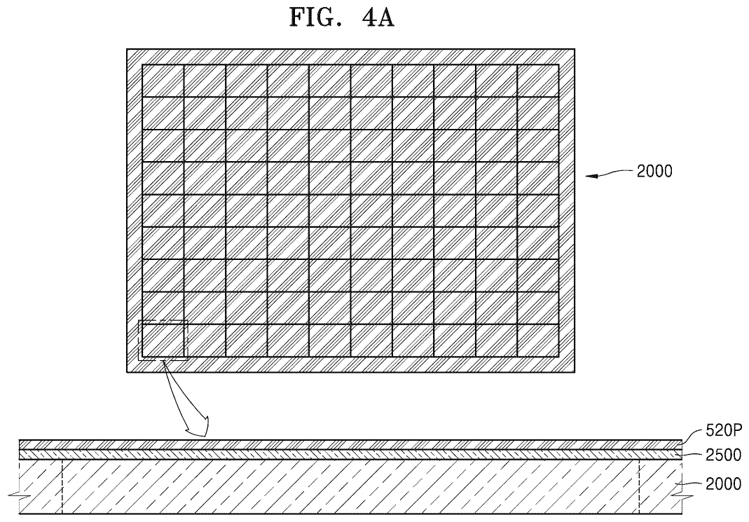

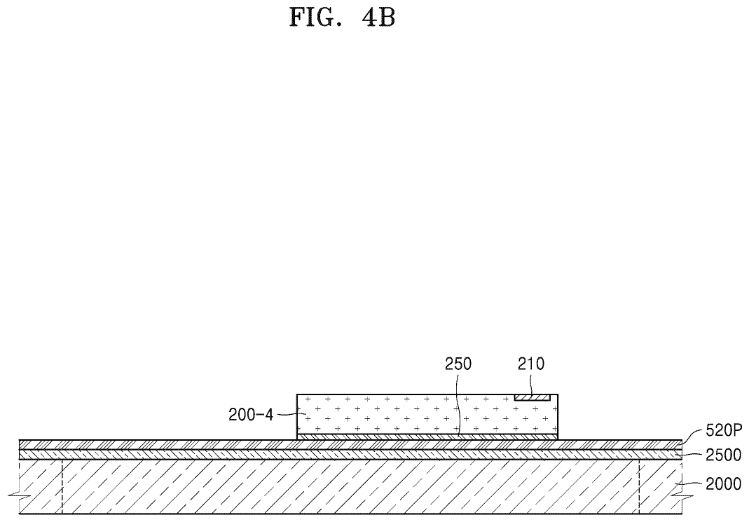

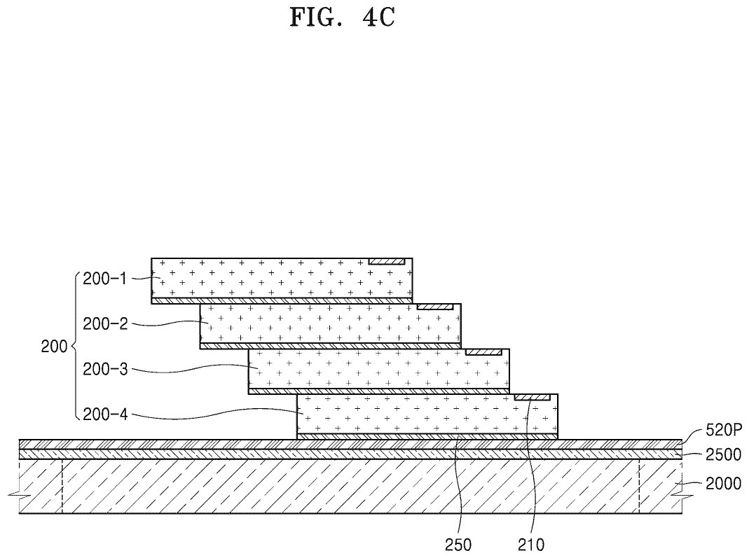

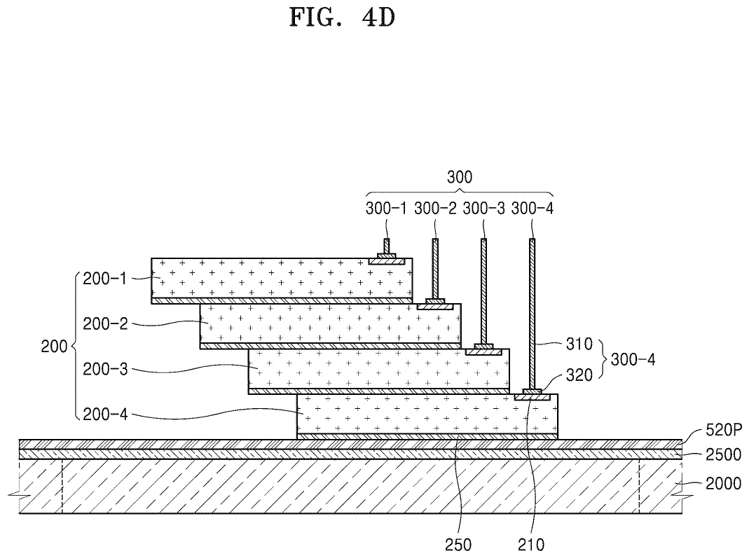

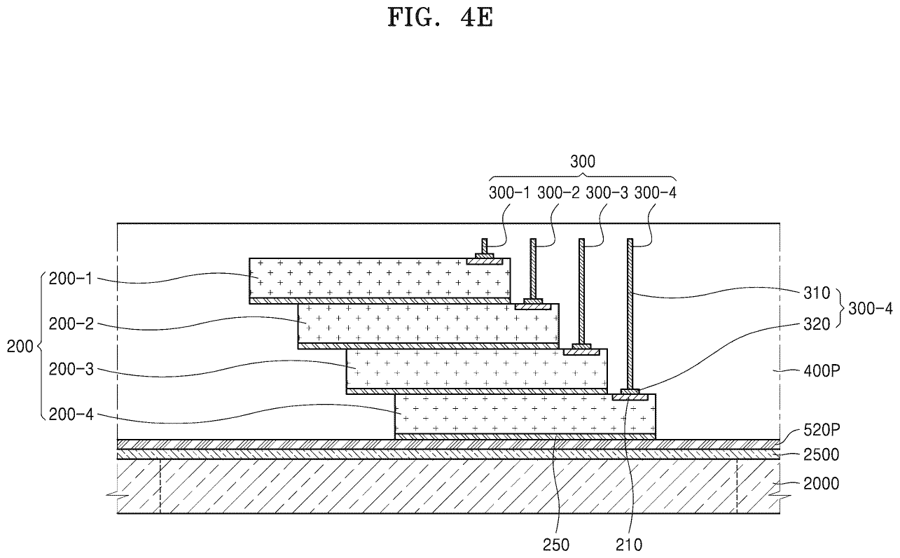

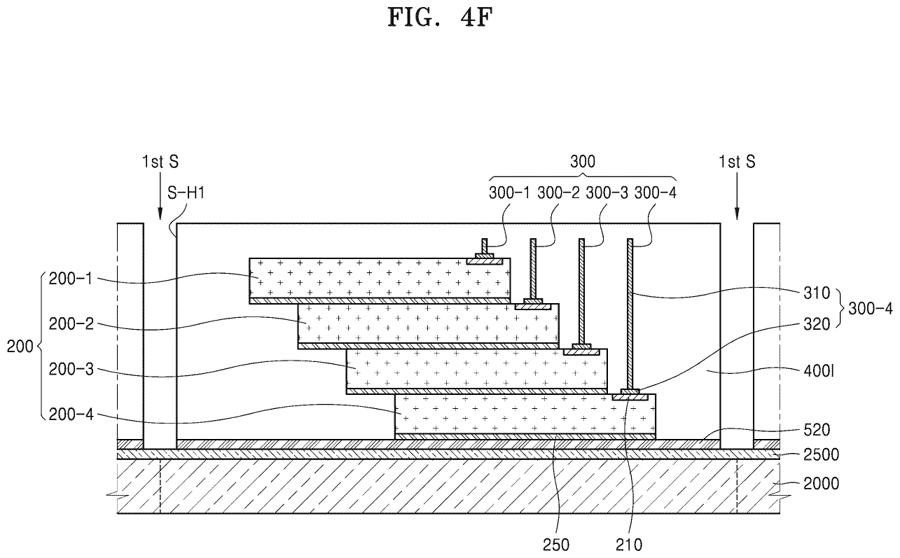

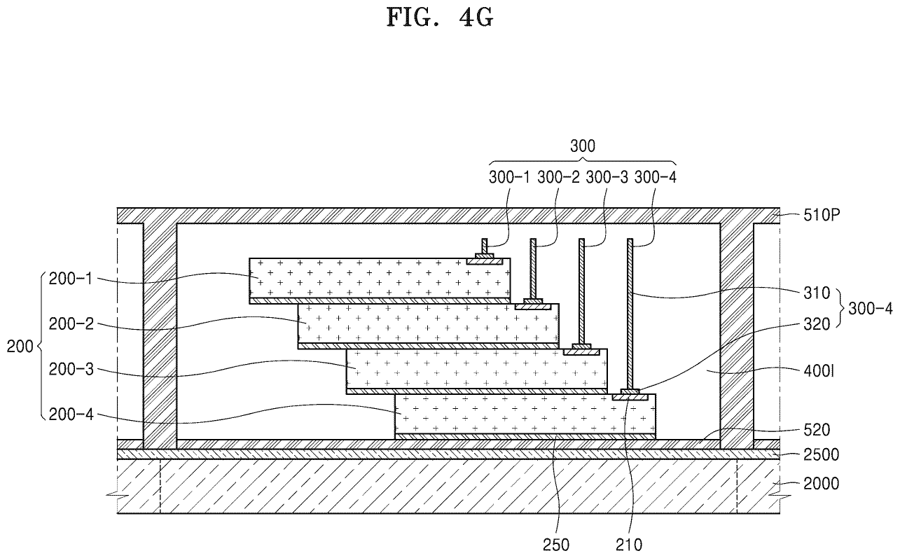

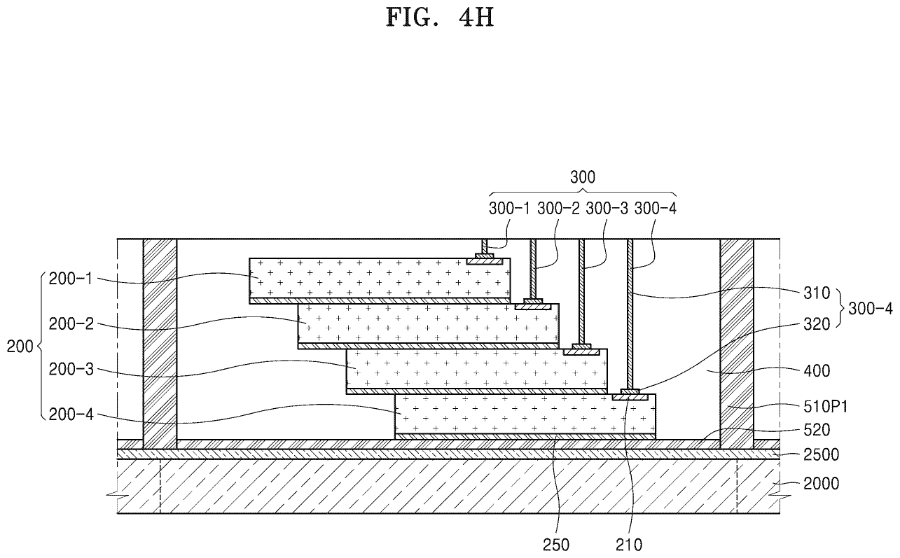

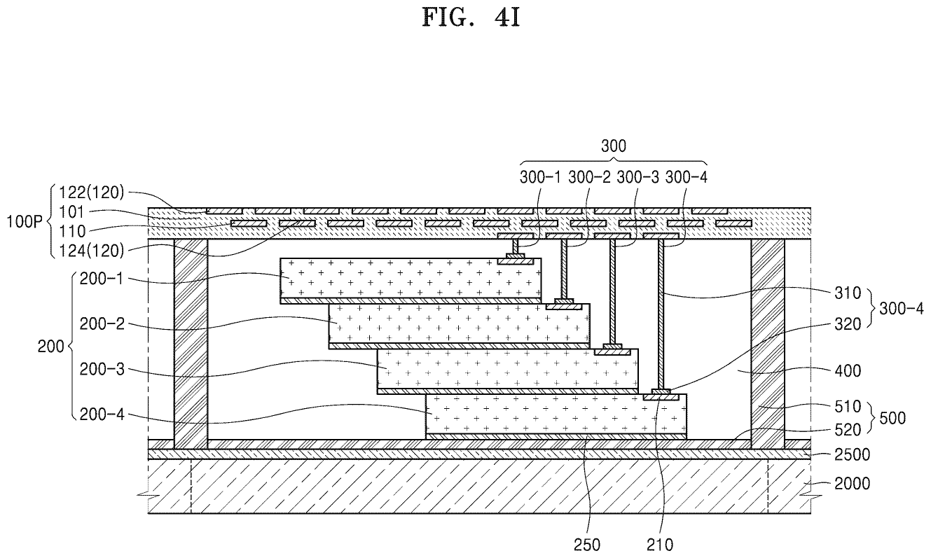

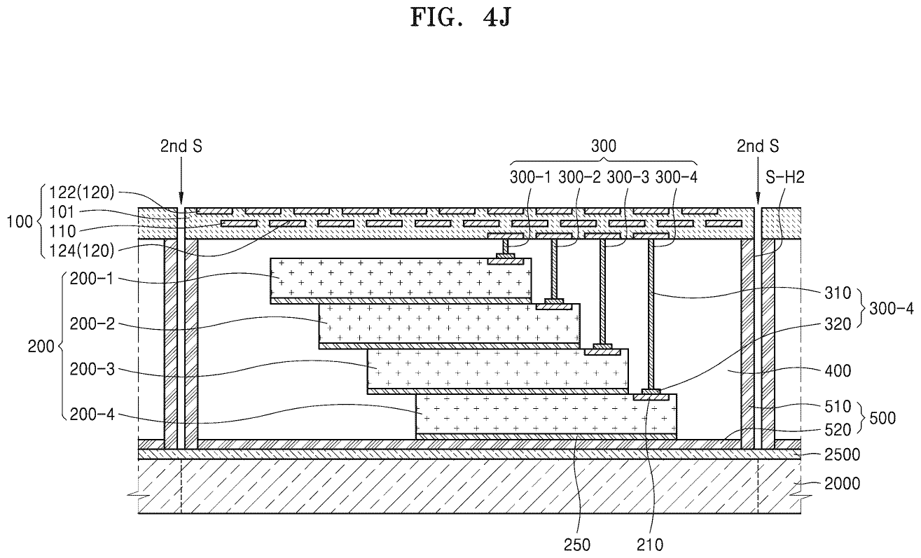

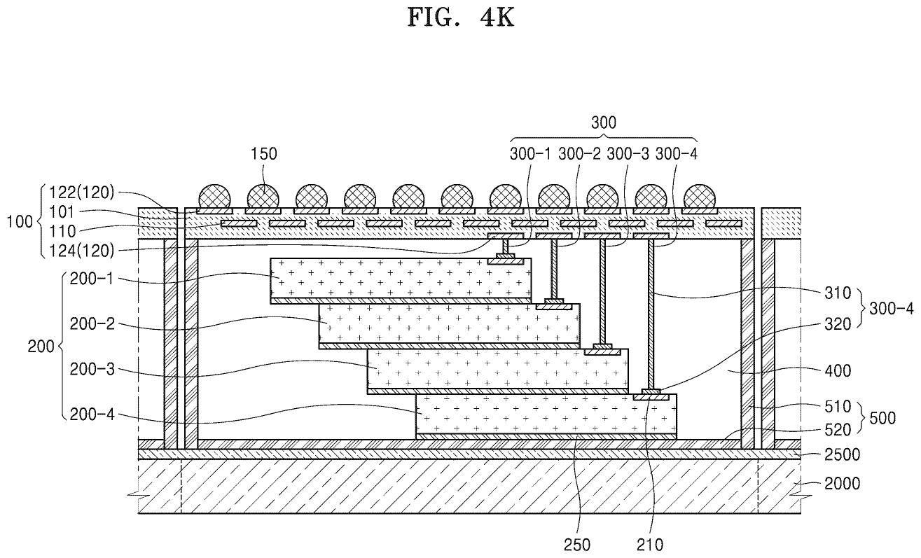

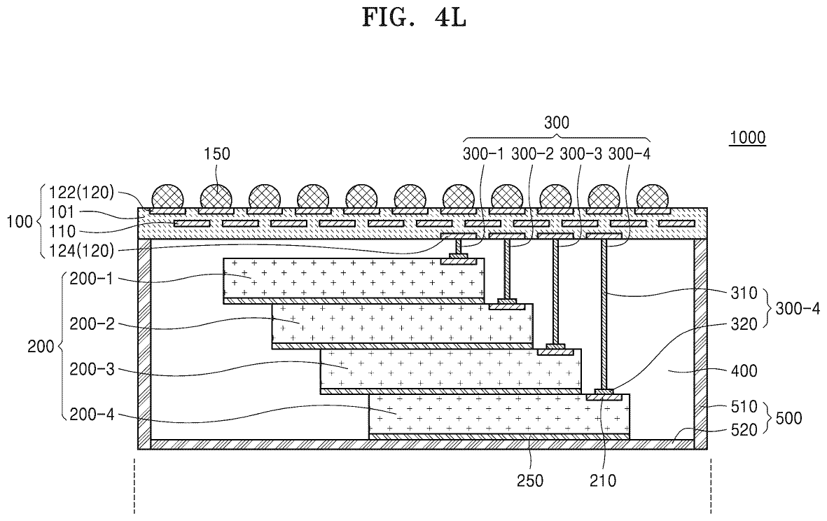

Meanwhile, contact portions may be formed at end portions of the extension portion in a general wire bonding structure. However, in the vertical wiring portion 300 of the semiconductor package 1000 according to an embodiment, in case of the fourth vertical wire 300-4, the contact portion 320 may be disposed at an upper end portion of the extension portion 310, and a contact portion may not be formed on a lower end portion of the extension portion 310. For example, the lower end portion of the extension portion 310 may be directly connected to the upper substrate pad 124 of the redistribution substrate 100. The structure of the fourth vertical wire 300-4 may be due to the process of forming the vertical wire. A process of forming the vertical wire will be described in more detail with reference to the description of a method of manufacturing the semiconductor package of FIGS. 4A through 4L.

In the semiconductor package 1000 of an embodiment, since the vertical wiring portion 300 is disposed between the redistribution substrate 100 and the chip stack structure 200, the overall size of the semiconductor package 1000 may be reduced. For example, in the case of a general wire bonding structure, a certain amount of space may be secured in the horizontal and vertical directions based on the curved shape of the wire, and the overall size of the semiconductor package may increase due to this space. On the other hand, in the case of vertical wires of the vertical wiring portion 300 of the semiconductor package 1000 according to an embodiment, the vertical wires extend in the vertical direction and may be connected to the redistribution substrate 100 so that an additional space is not required and the size of the semiconductor package 1000 may be reduced.

The sealing member 400 may be arranged on the redistribution substrate 100 and may be configured to seal the chip stack structure 200 and the vertical wiring portion 300. The sealing member 400 may be configured to prevent semiconductor chips of the chip stack structure 200 from being contaminated by external foreign substances. Also, the sealing member 400 may protect the semiconductor package 1000 from an external shock.

Specifically, the sealing member 400 may cover a lower surface and side surfaces of the chip stack structure 200 on the redistribution substrate 100. For example, the sealing member 400 may cover a lower surface and side surfaces of the first semiconductor chip 200-1 on the redistribution substrate 100 and may cover a part of an exposed lower surface and side surfaces of each of the second through fourth semiconductor chips 200-2 through 200-4. Also, the sealing member 400 may cover a part of the adhesive layer 250 on the exposed upper surface of the first through third semiconductor chips 200-1 through 200-3. In a case that the sealing member 400 covers the entire lower surface of the first semiconductor chip 200-1, the sealing member 400 may fill a space between the redistribution substrate 100 and the chip stack structure 200.

The sealing member 400 may cover side surfaces of the vertical wiring portion 300 on the redistribution substrate 100. For example, the sealing member 400 may cover side surfaces of the extension portion 310 of each of vertical wires of the vertical wiring portion 300 and may cover a lower surface of the contact portion 320.

The sealing member 400 may have a quadrangular column shape to correspond to the shape of the redistribution substrate 100. Thus, the sealing member 400 may have four side surfaces corresponding to four sides of the redistribution substrate 100, a lower surface being in contact with the redistribution substrate 100, and an upper surface facing the lower surface. The upper surface of the sealing member 400 may form substantially the same plane with the adhesive layer 250 on the upper surface of the chip stack structure 200, which may be the upper surface of the adhesive layer 250 of the fourth semiconductor chip 200-4.

The sealing member 400 may include an insulating material, for example, a thermosetting resin such as an epoxy resin, a thermoplastic resin such as polyimide, or a resin including a reinforcing material such as an inorganic filler. For example, the sealing member 400 may include AJINOMOTO BUILD-UP FILM® (ABF), FR-4, BT resin, or the like. Also, the sealing member 400 may include a molding material such as an epoxy molding compound (EMC), or a photosensitive material such as a photo imageable encapsulant (PIE). However, the material of the sealing member 400 is not limited to the above-described materials.

The semiconductor package 1000 according to an embodiment may have a comparatively small size. For example, the semiconductor package 1000 has a thickness of about 1 millimeter (mm) in the z-direction, and may have a width of about several mm to about 10 mm in the x- and y-directions. However, the size of the semiconductor package 1000 is not limited to the above numerical range. Meanwhile, based on the structure of the semiconductor package 1000, the sealing member 400 may be smaller than the entire size of the semiconductor package 1000. For example, the sealing member 400 may have a thickness of, for example, 1 mm or less. However, the thickness of the sealing member 400 is not limited to the above numerical range.

The heat dissipation metal member 500 may have a structure that covers the sealing member 400. The heat dissipation metal member 500 may be configured to effectively dissipate heat from the semiconductor package 1000 to the outside. For example, heat generated from semiconductor chips of the chip stack structure 200 may be effectively discharged through the heat dissipation metal member 500. In order to maximize the heat dissipation function, the heat dissipation metal member 500 may include a metal having high thermal conductivity. For example, the heat dissipation metal member 500 may include copper Cu, nickel (Ni), Al, Sn, Au, or Ag. However, the material of the heat dissipation metal member 500 is not limited to the above-described metals. In the semiconductor package 1000 according to an embodiment, the heat dissipation metal member 500 may include Cu, for example.

As shown in FIG. 1A, heat generated from a semiconductor chip in a lower part of the chip stack structure 200 may be discharged through the top plate 520 of the heat dissipation metal member 500 through semiconductor chips stacked thereon. Thus, the adhesive layer 250 for coupling adjacent semiconductor chips may include a material having high thermal conductivity. For example, the adhesive layer 250 may be a thermal interface adhesive layer. The adhesive layer 250 implemented as a thermal interface adhesive layer may include a thermal interface material (TIM), a thermally conductive resin, a thermally conductive polymer, or a silicon oxide or silicon nitride such as SiO₂ or SiCN. Here, the TIM may include a material having high thermal conductivity, that is, a material having low thermal resistance, such as a grease, tape, elastomer filling pad, or phase transition material.

Meanwhile, the heat dissipation metal member 500 may be configured to inhibit or block external electromagnetic wave noise. For example, the ground may be connected to the heat dissipation metal member 500, and the heat dissipation metal member 500 may inhibit or block electro-magnetic interference (EMI).

The heat dissipation metal member 500 may include a side plate 510 and an upper plate 520. The side plate 510 may cover four side surfaces of the sealing member 400. The upper plate 520 may cover an upper surface of the sealing member 400. Also, the upper plate 520 may cover the upper surface of the chip stack structure 200. For example, the fourth semiconductor chip 200-4, which is the uppermost semiconductor chip of the chip stack structure 200, may be attached to the upper plate 520 through the adhesive layer 250.

The heat dissipation metal member 500 may be connected to the ground pad 10. The ground pad 10 may be connected to an electrical ground of the redistribution substrate 100. The ground pad 10 may be a pad of the substrate pad 120. The ground pad 10 may be a pad of the upper substrate pad 124 disposed on the upper surface of the body insulating layer 101. In an example, the ground pad 10 may be omitted, and the heat dissipation metal member 500 may be connected to an external ground. The external ground may be provided separately from the redistribution substrate 100.

As can be seen through a manufacturing process of the semiconductor package 1000 of FIGS. 4A through 4L, the side plate 510 and the upper plate 520 may be formed at different times. Accordingly, the side plate 510 and the upper plate 520 may include different metals or the same metal. In addition, even when the side plate 510 and the upper plate 520 include the same metal, the side plate 510 and the upper plate 520 may have different characteristics, such as surface roughness. For example, the upper plate 520 may have a lower surface roughness than the side plate 510. That is, the surface of the upper plate 520 may be smoother than the surface of the side plate 510.

In a case that portions of the heat dissipation metal member 500 have different surface roughness, a heat flux of the heat dissipation metal member 500 may be tuned. For example, an effective contact area of the upper plate 520 may be increased by reducing the surface roughness thereof. The relative reduction in the surface roughness of the upper plate 520 may promote heat flux through the upper plate 520, relative to the side plate 510. In another case, the side plate 510 may have a smooth surface, relative to the upper plate 520, which may promote heat flux through the side plate 510.

Meanwhile, in FIG. 1A, a boundary line is displayed between the side plate 510 and the upper plate 520 that may indicate that the side plate 510 and the upper plate 520 include different metals or that the side plate 510 and the upper plate 520 have different physical properties, such as surface roughness, even though they are made of the same metal. Furthermore, the side plate 510 may contact the side surface of the upper plate 520. In other words, the upper portion of the vertical side surface of the side plate 510 may be coupled to the side surface of the upper plate 520.

In the semiconductor package 1000 of an embodiment, since the vertical wiring portion 300 may be disposed between the redistribution substrate 100 and the chip stack structure 200, the overall size of the semiconductor package 1000 may be reduced. In addition, the semiconductor package 1000 of an embodiment may have high heat dissipation characteristics by including a heat dissipation metal member 500 surrounding the sealing member 400. Meanwhile, the heat dissipation metal member 500 may be connected to the ground 10 to perform an electromagnetic interference (EMI) shielding function.

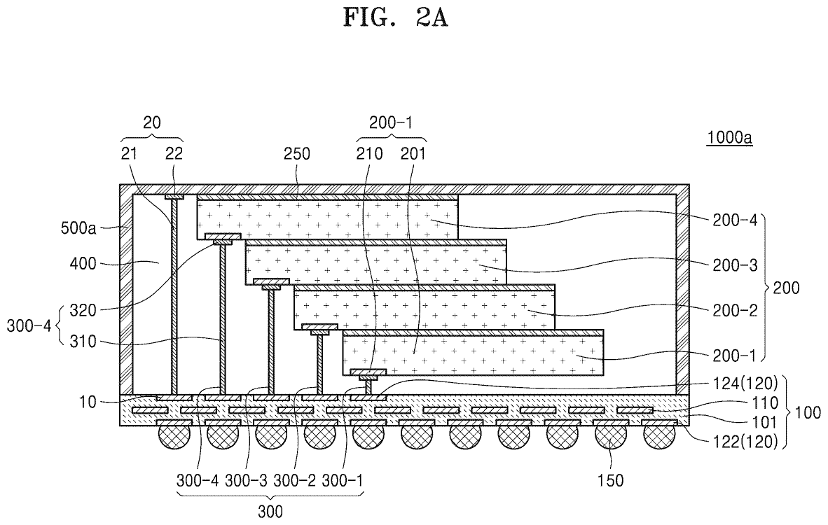

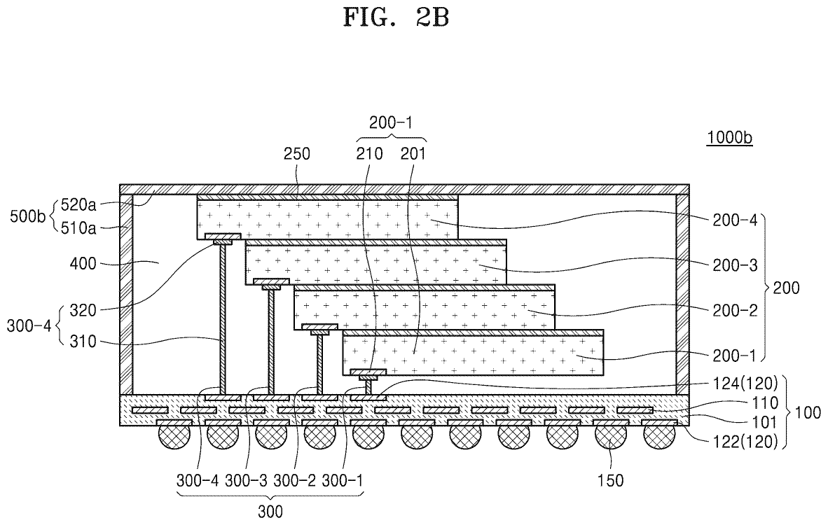

FIG. 2A and FIG. 2B are cross-sectional views of a semiconductor package according to embodiments. The contents already described in the description of FIG. 1A and FIG. 1B may be briefly described or omitted.

Referring to FIG. 2A, a semiconductor package 1000a of an embodiment may be different from the semiconductor package 1000 of FIG. 1A in a heat dissipation metal member 500a. Specifically, the semiconductor package 1000a according to an embodiment may include a redistribution substrate 100, a chip stack structure 200, a vertical wiring portion 300, a sealing member 400, and the heat dissipation metal member 500a. The redistribution substrate 100, the chip stack structure 200, the vertical wiring portion 300, and the sealing member 400 is the same or similar to that described in the context of the semiconductor package 1000 of FIG. 1A.

In the semiconductor package 1000a of an embodiment, the heat dissipation metal member 500a may include a side plate covering side surfaces of the sealing member 400 and an upper plate covering the upper surface of the sealing member 400. However, the side plate and the upper plate of the heat dissipation metal member 500a may include the same metal. In addition, the side plate and the upper plate of the heat dissipation metal member 500a may have substantially the same physical characteristics, such as surface roughness. Accordingly, in FIG. 2A, the heat dissipation metal member 500a is shown integrally without distinction between the side plate and the upper plate by the boundary line.

Referring to FIG. 2A, a ground vertical wiring portion 20 may be provided. The ground vertical wiring portion 20 may be electrically connected between the ground pad 10. The ground vertical wiring portion 20 may include a ground vertical wire 21 and a ground contact portion 22. The ground contact portion 22 may be electrically connected to the heat dissipation metal member 500a. The vertical wiring portion 20 may be formed the same as or similar to the vertical wiring portion 300.

Other contents of the heat dissipation metal member 500a may be the same as those of the heat dissipation metal member 500 of the semiconductor package 1000 of FIG. 1A.

Referring to FIG. 2B, a semiconductor package 1000b of an embodiment may be different from the semiconductor package 1000 of FIG. 1A in a heat dissipation metal member 500b. Specifically, the semiconductor package 1000b according to an embodiment may include a redistribution substrate 100, a chip stack structure 200, a vertical wiring portion 300, a sealing member 400, and the heat dissipation metal member 500b. The redistribution substrate 100, the chip stack structure 200, the vertical wiring portion 300, and the sealing member 400 may the same or similar to that described in the context of the semiconductor package 1000 of FIG. 1A.

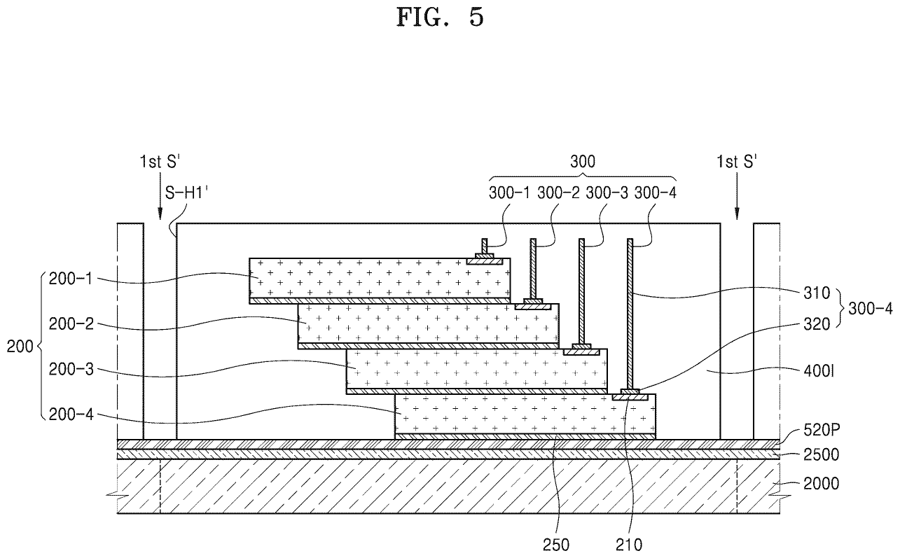

In the semiconductor package 1000b of an embodiment, the heat dissipation metal member 500b may include a side plate 510a covering side surfaces of the sealing member 400 and an upper plate 520a covering the upper surface of the sealing member 400. However, the coupling structure of the side plate 510a and the upper plate 520a of the heat dissipation metal member 500b may be different from the heat dissipation metal member 500 of the semiconductor package 1000 of FIG. 1A. Specifically, the side plate 510a may contact the lower surface of the upper plate 520a. In other words, the horizontal upper surface of the side plate 510a may be coupled to the outer portion of the lower surface of the upper plate 520a. Such a structural difference between the heat dissipation metal member 500 and the heat dissipation metal member 500b may be caused by a difference in a manufacturing process. This will be described in more detail in the description of FIG. 4F and FIG. 5.

Other contents of the heat dissipation metal member 500b may be the same or similar to as those of the heat dissipation metal member 500 of the semiconductor package 1000 of FIG. 1A.

FIG. 3A and FIG. 3B are cross-sectional views of a semiconductor package according to some embodiments. The contents already described in the description of FIG. 1A, FIG. 2A, and FIG. 2B may be briefly described or omitted.

Referring to FIG. 3A, the semiconductor package 1000c of an embodiment may be different from the semiconductor package 1000 of FIG. 1A in the structure of the chip stack structure 200a and the vertical wiring portion 300a. Specifically, the semiconductor package 1000c according to an embodiment may include a redistribution substrate 100, a chip stack structure 200, a vertical wiring portion 300, a sealing member 400, and the heat dissipation metal member 500. The redistribution substrate 100, the sealing member 400, and the heat dissipation metal member 500 may be the same or similar to that described in the context of the semiconductor package 1000 of FIG. 1A.

In the semiconductor package 1000c according to an embodiment, the chip stack structure 200a may include semiconductor chips stacked in a zigzag structure. Specifically, in the chip stack structure 200a, a third semiconductor chip 200a-3 may be arranged to protrude to the right in the x-direction from a second semiconductor chip 200a-2 and a fourth semiconductor chip 200a-4, and the second semiconductor chip 200a-2 may be arranged to protrude to the left in the x-direction from a first semiconductor chip 200a-1 and the third semiconductor chip 200a-3. Thus, in the third semiconductor chip 200a-3, a portion of the lower surface on the right side in the x-direction may be exposed by the second semiconductor chip 200a-2, and in the second semiconductor chip 200a-2 and the fourth semiconductor chip 200a-4, a portion of the lower surface on the left side in the x-direction may be exposed. The entire bottom surface of the first semiconductor chip 200a-1 may be exposed.

The positions of vertical wires of the vertical wiring portion 300a may be disposed according to the structure of the chip stack structure 200a. For example, each of the first vertical wires 300a-1, the second vertical wires 300a-2, and the fourth vertical wires 300a-4 may be disposed on the left side in the x-direction in the corresponding semiconductor chip, and the third vertical wires 300a-3 may be disposed on the right side in the x-direction in the third semiconductor chip 200a-3. In the case of the first vertical wires 300a-1, the lower surface of the first semiconductor chip 200a-1 may be exposed, and the first vertical wires 300a-1 may be disposed at any position on the lower surface of the first semiconductor chip 200a-1, such as on the right side of the first semiconductor chip 200a-1 in the x-direction.

In the structure of the chip stack structure 200a of the semiconductor package 1000c of an embodiment, the semiconductor chips may have opposite offsets the x-direction. For example, the first semiconductor chip 200a-1 and the third semiconductor chip 200a-3 may protrude to the right in the x-direction. That is, the third semiconductor chip 200a-3 may protrude more to the right in the x-direction than the first semiconductor chip 200a-1. This offset may secure a path of the third vertical wires 300a-1 connected to the third semiconductor chip 200a-3 in the z-direction. Similarly, the fourth semiconductor chip 200a-4 may protrude more than the second semiconductor chip 200a-2 to the left in the x-direction.

Other contents of the chip stack structure 200a and the vertical wiring portion 300a may be the same or similar as those described for the chip stack structure 200 and the vertical wiring portion 300 of the semiconductor package 1000 of FIG. 1A.

Referring to FIG. 3B, a semiconductor package 1000d of an embodiment may be different from the semiconductor package 1000 of FIG. 1A in the structure of the chip stack structure 200b and the vertical wiring portion 300b. Specifically, the semiconductor package 1000d according to an embodiment may include a redistribution substrate 100, a chip stack structure 200b, a vertical wiring portion 300b, a sealing member 400, and a heat dissipation metal member 500. The redistribution substrate 100, the sealing member 400, and the heat dissipation metal member 500 may be the same or similar to that described in the context of the semiconductor package 1000 of FIG. 1A.

In the semiconductor package 1000d according to an embodiment, the chip stack structure 200b may include semiconductor chips stacked in zigzag structure of a Z-shape. Specifically, in the chip stack structure 200b, a second semiconductor chip 200b-2 may be arranged to protrude to the right in the x-direction from a first semiconductor chip 200b-1 and a third semiconductor chip 200b-3. Thus, a portion of the right lower surface of the second semiconductor chip 200b-2 may be exposed in the x-direction, and portions of left lower surfaces of the third semiconductor chip 200b-3 and the fourth semiconductor chip 200b-4 may be exposed in the x-direction. The entire lower surface of the first semiconductor chip 200b-1 may be exposed.

The positions of vertical wires of the vertical wiring portion 300b may be disposed according to the structure of the chip stack structure 200b. For example, each of the first vertical wires 300b-1 and the second vertical wires 300b-2 may be disposed on the right side in the x-direction in the corresponding semiconductor chip, and each of the third vertical wires 300b-3 and the fourth vertical wires 300b-4 may be disposed on the left side in the x-direction in the corresponding semiconductor chip. In the case of the first vertical wires 300b-1, the lower surface of the first semiconductor chip 200b-1 may be exposed, and the first vertical wires 300b-1 may disposed at any position on the lower surface of the first semiconductor chip 200b-1, such as on the left side of the first semiconductor chip 200b-1 in the x-direction.

Although various stacked structures of the chip stack structure have been described, the stacked structure of the chip stack structure is not limited thereto. For example, in a case that at least a part of the lower surface of each of the semiconductor chips of the chip stack structure is exposed, and the vertical wires of the vertical wiring portion may be connected through a part of the exposed lower surface, and various stacking structures may be employed in the chip stack structure. For example, some of the semiconductor chips of the chip stack structure have a part of the lower surface exposed in the x-direction, and some of the semiconductor chips of the chip stack structure have a part exposed in the y-direction.

FIGS. 4A through 4L are cross-sectional views showing processes of a method of manufacturing a semiconductor package, according to an embodiment. The descriptions of FIG. 1A and FIG. 1B will be described together, and the descriptions of FIG. 1A, FIG. 1B, FIG. 2A, FIG. 2B, FIG. 3A, and FIG. 3B will be briefly described or omitted.

Referring to FIG. 4A, in a method of manufacturing a semiconductor package of an embodiment, a panel 2000 having a first panel metal layer 520P formed on an upper surface thereof may be prepared. The panel 2000 may include glass. However, the material of the panel 2000 is not limited to glass. For example, the panel 2000 may include silicon, an organic material, or plastic. In some embodiments, the panel 2000 may be referred to as a glass core including glass. The panel 2000 may have a size in which a plurality of redistribution substrates may be combined. For example, in the upper plan view of FIG. 4A, each square may correspond to a redistribution substrate 100. Specifically, in the lower cross-section of FIG. 4A, a portion between dotted lines of the panel 2000 may correspond to the redistribution substrate 100 of any of FIG. 1A, FIG. 1B, FIG. 2A, FIG. 2B, FIG. 3A, or FIG. 3B.

The first panel metal layer 520P may have a size corresponding to the panel 2000. The first panel metal layer 520P may be disposed on the upper surface of the panel 2000 with a panel adhesive layer 2500 interposed therebetween. The first panel metal layer 520P may include a seed layer and a plating layer. The seed layer and the plating layer may include a metal. For example, the seed layer and the plating layer may include Cu. However, the materials of the seed layer and the plating layer are not necessarily limited to Cu. The first panel metal layer 520P may constitute the upper plate 520 in the structure of the final semiconductor package 1000. Thus, the upper plate 520 may also include a seed layer and a plating layer. Meanwhile, the panel adhesive layer 2500 may be a type of adhesive layer that is easily separated. The panel adhesive layer 2500 may be separated from the heat dissipation metal member 500 when the panel 2000 is separated from the semiconductor package 1000.

Referring to FIG. 4B, after preparing the panel 2000, the fourth semiconductor chip 200-4 may be attached to the first panel metal layer 520P of the panel 2000 through the adhesive layer 250. The adhesive layer 250 may be a DAF. However, the adhesive layer 250 is not necessarily limited to the DAF, and may include a TIM, a thermally conductive resin, a thermally conductive polymer, or a silicon oxide or silicon nitride such as SiO₂ or SiCN.

The fourth semiconductor chip 200-4 may correspond to the uppermost semiconductor chip of the chip stack structure 200. In addition, the fourth semiconductor chip 200-4 may correspond to a structure in which the upper and lower parts may be inverted compared to the fourth semiconductor chip 200-4 of the chip stack structure 200 of FIG. 1A. Thus, in FIG. 4B, the upper surface of the fourth semiconductor chip 200-4 may be an active surface, and a lower surface of the fourth semiconductor chip 200-4 may be a non-active surface. In addition, the chip pads 210 may be disposed on the upper surface of the fourth semiconductor chip 200-4, and may be disposed on the right side in the x-direction along the y-direction. That is, in the fourth semiconductor chip 200-4, the chip pads 210 may correspond to a portion where the upper surface portion on the right side is exposed in the x-direction.

Referring to FIG. 4C, after the fourth semiconductor chip 200-4 is attached, a third semiconductor chip 200-3, a second semiconductor chip 200-2, and a first semiconductor chip 200-1 may be sequentially stacked on the fourth semiconductor chip 200-4 in a step structure using the adhesive layer 250. In FIG. 4C, each of the third semiconductor chip 200-3, the second semiconductor chip 200-2, and the first semiconductor chip 200-1 may have an upper surface of an active surface and a lower surface of a non-active surface thereof. Furthermore, the chip pads 210 of each of the third semiconductor chip 200-3, the second semiconductor chip 200-2, and the first semiconductor chip 200-1 may be disposed on the right side of the corresponding semiconductor chip in the x-direction.

The first through fourth semiconductor chips 200-1 through 200-4 may constitute a chip stack structure 200 having a step structure. In addition, the chip pads 210 of each of the fourth semiconductor chip 200-4, the third semiconductor chip 200-3, and the second semiconductor chip 200-2 may be exposed upward based on the step structure of the chip stack structure 200.

In the process of FIG. 4C, a chip stack structure may be formed by stacking semiconductor chips in a zigzag structure or a Z-type step structure. The chip stack structure 200a having a zigzag structure may be completed with the semiconductor package 1000c of FIG. 3A later in FIG. 4L, and the chip stack structure 200b having a Z-type step structure may be completed with the semiconductor package 1000d of FIG. 3B later in FIG. 4L.

Referring to FIG. 4D, after the chip stack structure 200 is configured, vertical wires may be formed on chip pads 210 of each of the first through fourth semiconductor chips 200-1 through 200-4. Specifically, first vertical wires 300-1 may be formed on the chip pads 210 of the first semiconductor chip 200-1, second vertical wires 300-2 may be formed on the chip pads 210 of the second semiconductor chip 200-2, third vertical wires 300-3 may be formed on the chip pads 210 of the third semiconductor chip 200-3, and fourth vertical wires 300-4 may be formed on the chip pads 210 of the fourth semiconductor chip 200-4. The first vertical wires 300-1, the second vertical wires 300-2, the third vertical wires 300-3, and the fourth vertical wires 300-4 may constitute the vertical wiring portion 300.

Referring to the formation of vertical wires, a first end portion of the wire may be bonded to the chip pad 210 of the semiconductor chip using a wire bonding machine. The wire may include a metal such as gold, silver, copper, or platinum, or an alloy thereof that can be welded to the chip pad 210 by ultrasonic energy and/or heat. Then, using a wire bonding machine, a second end portion of the wire may be pulled from the bottom to the top in a direction away from the corresponding semiconductor chip, for example, in the z-direction. Thereafter, when the second end portion of the wire extends to an end position, the second end portion of the wire may be cut. Through this method, a vertical wire may be formed.

A lower end portion of the vertical wire may be bonded to the chip pad 210 to form the contact portion 320. As described herein, the contact portion 320 may have a larger planar area than the extension portion 310. In addition, in a case that the upper end portion of the vertical wire may be cut, a separate contact portion may not be formed.

As may be seen from FIG. 4D, the first vertical wire 300-1, the second vertical wire 300-2, the third vertical wire 300-3, and the fourth vertical wire 300-4 may each have a same vertical height about the first panel metal layer 520P. For example, the length in the z-direction may be increased in the order of the first vertical wire 300-1, the second vertical wire 300-2, the third vertical wire 300-3, and the fourth vertical wire 300-4. Accordingly, the fourth vertical wire 300-4 may be the longest. For reference, previously, when the thickness of the sealing member 400 is less than about 1 mm, considering the thickness of the semiconductor chip, the fourth vertical wire 300-4 may be smaller than the thickness of the sealing member 400, and accordingly, less than 1 about mm. However, the length of the fourth vertical wire 300-4 is not limited to the above numerical range.

Referring to FIG. 4D, the first vertical wire 300-1 may be omitted, and the vertical height of the second vertical wire 300-2, the third vertical wire 300-3, and the fourth vertical wire 300-4 may be about the same as the upper surface of the first semiconductor chip 200-1. In a case that the first vertical wire 300-1 is omitted, the first semiconductor chip 200-1 may be directly bonded to the upper substrate pad 124 disposed on an upper surface of the body insulating layer 101. For example, a height of the semiconductor package 1000 may be reduced.

Referring to FIG. 4E, after the vertical wiring portion 300 is configured, a panel sealing member 400P covering the chip stack structure 200 and the vertical wiring portion 300 may be formed on the first panel metal layer 520P of the panel 2000. The panel sealing member 400P may cover an upper surface of the chip stack structure 200, for example, an upper surface of the first semiconductor chip 200-1. In addition, the panel sealing member 400P may cover the upper end portions of vertical wires of the vertical wiring portion 300. The panel sealing member 400P may include, for example, EMC. However, the material of the panel sealing member 400P is not limited to EMC.

Referring to FIG. 4F, after the panel sealing member 400P is formed, the panel sealing member 400P may be cut into a size corresponding to the semiconductor package through a first sawing (1st S) process. The first sawing (1st S) process may be performed using a laser or a blade. In the first sawing (1stS) process, the first panel metal layer 520P may also be cut. Thus, as shown in FIG. 4F, the panel adhesive layer 2500 may be exposed on a bottom surface of a first sawing-groove S-H1.

In the first sawing (1st S) process, the first panel metal layer 520P may be divided into upper plates 520 corresponding to semiconductor packages to form the upper plate 520 of the heat dissipation metal member 500. Side surfaces of the upper plates 520 may be exposed at a lower portion of the first sawing-groove S-H1. In the first sawing (1st S) process, the panel sealing member 400P may be separated into initial sealing members 400I corresponding to semiconductor packages.

Referring to FIG. 4G, the second panel metal layer 510P may be formed after the first sawing (1stS) process. The second panel metal layer 510P may be formed through a plating process. In the plating process, the upper plates 520 exposed to the lower portion of the first sawing-groove S-H1 may act as a seed layer.

The second panel metal layer 510P may be disposed in the first sawing-groove S-H1 and may cover the upper surface of the initial sealing members 400I. The second panel metal layer 510P may fill the first sawing-groove S-H1 and may cover the upper surface of the initial sealing members 400I. Although the thickness of the second panel metal layer 510P on the upper surfaces of the initial sealing members 400I is uniformly illustrated in FIG. 4G, the thickness of the second panel metal layer 510P on the upper surface of the initial sealing members 400I may not be uniform. For example, the second panel metal layer 510P on the upper surface of the initial sealing members 400I may be thicker at a portion adjacent to the first sawing-groove S-H1, and may be thinner toward the center of each of the initial sealing members 400I in the x- and y-directions.

Referring to FIG. 4H, after the second panel metal layer 510P is formed, a part of the second panel metal layer 510P on the upper surface of the initial sealing members 400I and an upper part of the initial sealing members 400I may be removed. For example, the part of the second panel metal layer 510P on the upper surface of the initial sealing members 400I and the upper part of the initial sealing members 400I may be removed through a grinding process. Through the grinding process, the thickness of the initial sealing members 400I may be reduced, and the initial sealing members 400I may become the sealing members 400.

The grinding process may be used to expose the vertical wires of the vertical wiring portion 300. Thus, the upper end portions of the vertical wires of the vertical wiring portion 300 may be exposed from the sealing members 400 through the grinding process. Furthermore, through a grinding process, the upper surface of the second panel metal layer 510P1 filled with the first sawing groove S-H1 may be exposed from the sealing members 400.

Referring to FIG. 4I, after the grinding process, a panel redistribution substrate 100P may be formed on the upper surfaces of the sealing members 400. The panel redistribution substrate 100P may include a body insulating layer 101, a redistribution line 110, and a substrate pad 120. The panel redistribution substrate 100P may include a plurality of redistribution substrates 100 before being separated. Each of the plurality of redistribution substrates 100 of the panel redistribution substrate 100P is as described in the redistribution substrate 100 of the semiconductor package 1000 of FIG. 1A. The vertical wires of the vertical wiring portion 300 may be connected to the corresponding substrate pad 120 of the redistribution substrate 100.

Referring to FIG. 4J, after the panel redistribution substrate 100P is formed, the panel redistribution substrate 100P and the second panel metal layer 510P1 may be cut to correspond to the semiconductor package through a second sawing (2nd S) process. In the second sawing (2nd S) process, the panel redistribution substrate 100P may be separated into a plurality of redistribution substrates 100. In addition, in the second sawing (2nd S) process, the second panel metal layer 510P1 in the first sawing-home S-H1 may be divided into two parts to form the side plate 510 of the heat dissipation metal member 500. Meanwhile, the panel adhesive layer 2500 may be exposed to the bottom surface of the second sawing-groove S-H2.

Referring to FIG. 4K, after the second sawing (2nd S) process, an external connection terminal 150 may be formed on the redistribution substrate 100. The external connection terminal 150 may be formed on the substrate pad 120. The external connection terminal 150 is the same as the external connection terminal 150 of the semiconductor package 1000 of FIG. 1A.

Referring to FIG. 4L, the panel 2000 may be separated from the semiconductor packages 1000 after the external connection terminal 150 is formed. When the panel 2000 is separated, the panel adhesive layer 2500 may also be separated. Each of the semiconductor packages 1000 may correspond to the semiconductor package 1000 of FIG. 1A. Thus, in FIG. 4L, the semiconductor package 1000 of FIG. 1A may be completed. For reference, the semiconductor package 1000 of FIG. 4L may correspond to a shape in which the upper and lower parts may be inverted compared to the semiconductor package 1000 of FIG. 1A.

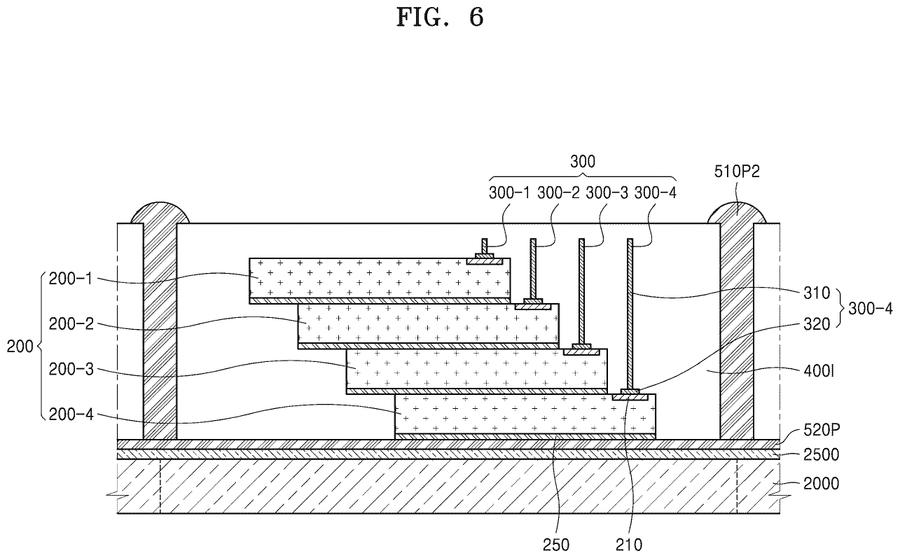

FIG. 5 and FIG. 6 are cross-sectional views showing processes of a method of manufacturing a semiconductor package, according to embodiments. The descriptions of FIG. 2B will be described together, and the descriptions of FIGS. 4A through 4L will be briefly described or omitted.

Referring to FIG. 5, in a method of manufacturing a semiconductor package according to an embodiment, processes of FIGS. 4A through 4E may be sequentially performed. That is, the chip stack structure 200, the vertical wiring portion 300, and the panel sealing member 400P may be formed on the first panel metal layer 520P of the panel 2000 through the processes of FIGS. 4A through 4E.

Thereafter, the panel sealing member 400P may be cut into a size corresponding to the semiconductor package through a first sawing (1st S′) process. In the first sawing (1st S′) process of a method of manufacturing the semiconductor package according to an embodiment, the first panel metal layer 520P may not be cut. Thus, as shown in FIG. 5, the upper surface of the first panel metal layer 520P may be exposed on the bottom surface of a first sawing-groove S-H1′. In the first sawing (1st S′) process, the panel sealing member 400P may be separated into initial sealing members 400I corresponding to semiconductor packages.

Subsequently, the process of FIGS. 4G through 4L may be performed to complete the semiconductor package 1000b of FIG. 2B. In addition, in the plating process of FIG. 4G, the first panel metal layer 520P exposed to the bottom surface of the first sawing-groove S-H1′ may act as the seed layer. In addition, in the second sawing (2nd S) process of FIG. 4J, the first panel metal layer 520P may be cut together with the second panel metal layer 510P1 to form the upper plate 520 of the heat dissipation metal member 500b.

Referring to FIG. 6, in a method of manufacturing a semiconductor package according to an embodiment, processes of FIGS. 4A through 4F may be sequentially performed. That is, the chip stack structure 200, the vertical wiring portion 300, and the panel sealing member 400P may be formed on the first panel metal layer 520P of the panel 2000 through the processes of FIGS. 4A through 4F, the first panel metal layer 520P may be separated into the upper plates 520 through the first sawing (1st S) process, and the panel sealing member 400P may be separated into initial sealing members 400I through the first sawing (1st S).

Thereafter, the second panel metal layer 510P2. The second panel metal layer 510P2 may be formed through a plating process. In the plating process, the upper plates 520 exposed to the lower portion of the first sawing-groove S-H1 may act as a seed layer. In a method of manufacturing the semiconductor package of an embodiment, the second panel metal layer 510P2 may fill the first sawing-groove S-H1 and cover only a part of upper surfaces of the initial sealing members 400I adjacent to the first sawing-groove S-H1. That is, the second panel metal layer 510P2 may not be formed on the upper surface of the inner portion of each of the initial sealing members 400I that are not adjacent to the first sawing-groove S-H1 in the x- and y-directions.

Subsequently, the process of FIGS. 4H through 4L may be performed to complete the semiconductor package 1000 of FIG. 1A.

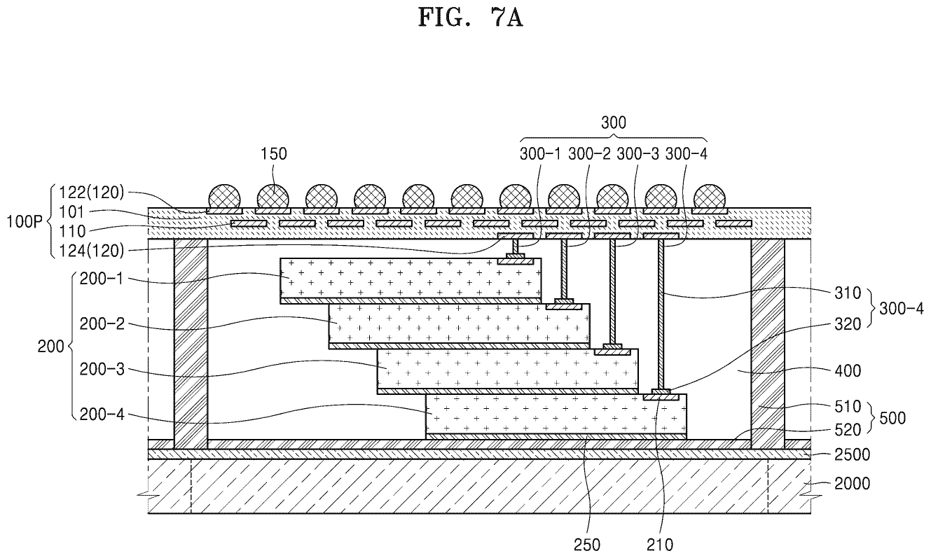

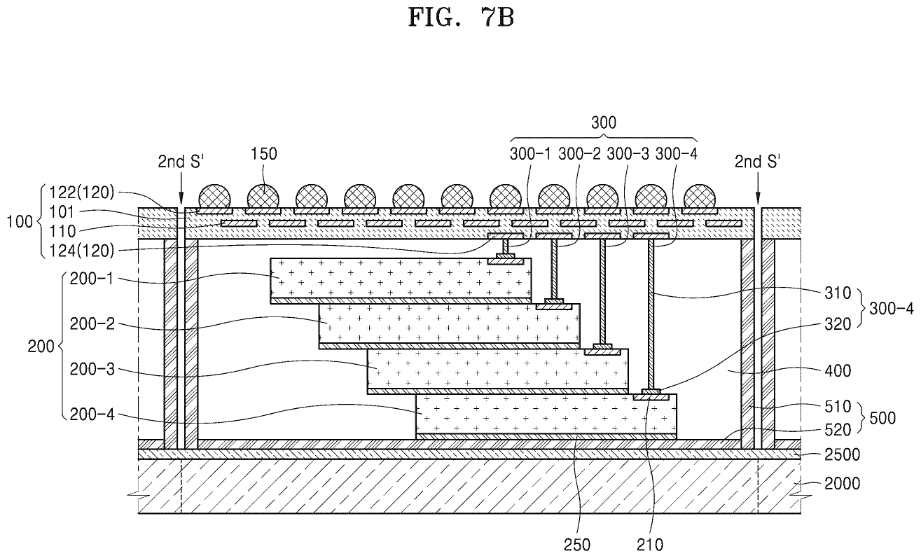

FIG. 7A and FIG. 7B are cross-sectional views schematically illustrating processes of a method of manufacturing a semiconductor package, according to an embodiment. The descriptions of FIG. 1A will be described together, and the descriptions of FIGS. 4A through 4L, FIG. 5, and FIG. 6 may be briefly described or omitted.

Referring to FIG. 7A, in a method of manufacturing a semiconductor package according to an embodiment, processes of FIGS. 4A through 4I may be sequentially performed. That is, the chip stack structure 200, the vertical wiring portion 300, the sealing member 400, and the redistribution substrate 100 may be formed on the upper plates 520 of the panel 2000 through the processes of FIGS. 4A through 4E.

Thereafter, instead of the second sawing process, an external connection terminal 150 may be formed on the panel redistribution substrate 100P. The external connection terminal 150 may be formed on the substrate pad 120 of the panel redistribution substrate 100. The external connection terminal 150 is the same as the external connection terminal 150 of the semiconductor package 1000 of FIG. 1A.

Referring to FIG. 7B, after the external connection terminal 150 is formed, the panel redistribution substrate 100P and the second panel metal layer 510P1 may be cut to correspond to the semiconductor package through a second sawing (2nd S′) process. In the second sawing (2nd S′) process, the panel redistribution substrate 100P may be separated into a plurality of redistribution substrates 100. In addition, in the second sawing (2nd S′) process, the second panel metal layer 510P1 in the first sawing-groove S-H1 may be divided into two parts to form the side plate 510 of the heat dissipation metal member 500. The panel adhesive layer 2500 may be exposed to the bottom surface of the second sawing-groove S-H2.

In the second sawing (2nd S′) process of a method of manufacturing a semiconductor package according to an embodiment, a mask covering the external connection terminal 150 may be formed. The mask may prevent contamination or damage of the external connection terminal 150 in the second sawing (2nd S′) process.

Subsequently, the process of FIG. 4L may be performed to complete the semiconductor package 1000 of FIG. 1A.

While the inventive concept has been particularly shown and described with reference to embodiments thereof, it will be understood that various changes in form and details may be made therein without departing from the spirit and scope of the following claims.

What is claimed is:

1. A semiconductor package comprising:
a redistribution substrate;
a chip stack structure disposed on the redistribution substrate and comprising a plurality of semiconductor chips disposed in a stack;
a vertical wiring portion connecting the chip stack structure to the redistribution substrate and comprising a plurality of vertical wires that extend in a direction perpendicular to an upper surface of the redistribution substrate;
a sealing member configured to seal at least a portion of the chip stack structure and the vertical wiring portion; and
a heat dissipation metal member disposed on side surfaces and an upper surface of the sealing member.

2. The semiconductor package of claim 1, wherein the redistribution substrate comprises a ground pad,
wherein the heat dissipation metal member comprises a metal, and
wherein the heat dissipation metal member is connected to an electrical ground through the ground pad.

3. The semiconductor package of claim 1, wherein the heat dissipation metal member comprises a metal disposed on the side surfaces and the upper surface of the sealing member.

4. The semiconductor package of claim 3, wherein a portion of the heat dissipation metal member on the upper surface of the sealing member and a portion of the heat dissipation metal member on the side surfaces of the sealing member have different surface roughness.

5. The semiconductor package of claim 1, wherein at least a part of the heat dissipation metal member comprises copper (Cu).

6. The semiconductor package of claim 1, wherein a portion of the heat dissipation metal member on the upper surface of the sealing member is formed of a first metal and a portion of the heat dissipation metal member on the side surfaces of the sealing member is formed of a second metal, different than the first metal.

7. The semiconductor package of claim 1, wherein the sealing member is disposed between a lowermost semiconductor chip of the chip stack structure and the redistribution substrate.

8. The semiconductor package of claim 1, wherein an uppermost semiconductor chip of the chip stack structure is adhered to the heat dissipation metal member on an upper surface of the sealing member by using an adhesive.

9. The semiconductor package of claim 8, wherein adjacent semiconductor chips in the chip stack structure are adhered to each other by an adhesive.

10. The semiconductor package of claim 1, wherein, in each of the plurality of semiconductor chips of the chip stack structure, a lower surface facing the redistribution substrate is an active surface, and the plurality of vertical wires connect a plurality of chip pads on the lower surface of each of the plurality of semiconductor chips to a plurality of upper substrate pads on an upper surface of the redistribution substrate.

11. The semiconductor package of claim 1, wherein the plurality of vertical wires are connected to a plurality of upper substrate pads disposed on an upper surface of the redistribution substrate, and a plurality of external connection terminals are disposed on a plurality of lower substrate pads on a lower surface of the redistribution substrate.

12. A semiconductor package comprising:
a redistribution substrate;
a chip stack structure disposed on and spaced apart from the redistribution substrate and comprising a plurality of semiconductor chips disposed in a stack;
a vertical wiring portion connecting the chip stack structure to the redistribution substrate and comprising a plurality of vertical wires that extend in a direction perpendicular to an upper surface of the redistribution substrate;
a sealing member configured to seal at least a portion of the chip stack structure and the vertical wiring portion and to fill a space between the redistribution substrate and the chip stack structure; and
a heat dissipation metal member disposed on side surfaces and an upper surface of the sealing member.

13. The semiconductor package of claim 12, wherein the heat dissipation metal member comprises a metal disposed on the side surfaces and the upper surface of the sealing member, and a portion of the heat dissipation metal member on the upper surface of the sealing member and a portion of the heat dissipation metal member on the side surfaces of the sealing member have different roughness.

14. The semiconductor package of claim 12, wherein, in each of the plurality of semiconductor chips of the chip stack structure, a lower surface facing the redistribution substrate is an active surface, and the plurality of vertical wires connect a plurality of chip pads on the lower surface of each of the plurality of semiconductor chips to a plurality of upper substrate pads on an upper surface of the redistribution substrate.

15. The semiconductor package of claim 12, further comprising a plurality of external connection terminals disposed on a lower surface of the redistribution substrate.

16. A semiconductor package comprising:
a redistribution substrate;
a chip stack structure disposed on the redistribution substrate and comprising a plurality of semiconductor chips disposed in a stack;
a vertical wiring portion connecting the chip stack structure to the redistribution substrate and comprising a plurality of vertical wires that extend between an upper surface of the redistribution substrate and a lower surface of each semiconductor chip of the chip stack structure; and
a heat dissipation metal member surrounding the chip stack structure and comprising an upper plate to which an uppermost semiconductor chip of the chip stack structure is adhered by a thermal interface adhesive layer.

17. The semiconductor package of claim 16, further comprising a sealing member configured to seal at least a portion of the chip stack structure and the vertical wiring portion on the redistribution substrate, wherein the chip stack structure is spaced apart from the redistribution substrate, and the sealing member is configured to fill a space between a lowermost semiconductor chip of the chip stack structure and the redistribution substrate.

18. The semiconductor package of claim 17, wherein the heat dissipation metal member comprises side plates covering side surfaces of the sealing member and the upper plate covering an upper surface of the sealing member, and the heat dissipation metal member comprises a metal.

19. The semiconductor package of claim 17, wherein a portion of the heat dissipation metal member covering an upper surface of the sealing member is formed of a first metal and a portion of the heat dissipation metal member covering side surfaces of the sealing member is formed of a second metal, different than the first metal.

20. The semiconductor package of claim 16, wherein, in each of the plurality of semiconductor chips of the chip stack structure, a lower surface facing the redistribution substrate is an active surface, and the vertical wires are configured to connect a plurality of chip pads on the lower surface of each of the plurality of semiconductor chips to a plurality of upper substrate pads on an upper surface of the redistribution substrate.
